(19) United States
(12) Patent Application Publication
(10) Pub. No.: US 2001/0010947 A1
(43) Pub. Date: Aug. 2, 2001

(54) Film ball grid array (BGA) semiconductor package

(75) Inventors: Kao-Yu Hsu, Kaohsiung Hsien (TW); Su Tao, Kaohsiung (TW); Shih-Chang Lee, Kaohsiung Hsien (TW)

Correspondence Address: LOWE HAUPTMAN GILMAN & BERNER, LLP, 1700 Diagonal Road, Suite 310, Alexandria, VA, 22314, US

(73) Assignee: Advanced Semiconductor Engineering, Inc.

(21) Appl. No.: 09/783,983

(22) Filed: Feb. 16, 2001

Related U.S. Application Data
(62) Division of application No. 09/444,364, filed on Nov. 22, 1999, now abandoned.

(51) Int. Cl. H01L 21/44; H01L 21/48; H01L 21/50

(52) U.S. Cl. 438/118; 438/126; 438/124

(57) ABSTRACT

A film BGA package generally comprises a semiconductor chip disposed on a flexible film substrate. The flexible film substrate includes a plurality of solder pads formed on the central area thereof and a plurality of chip connection pads formed on the peripheral area thereof. The semiconductor chip is securely attached onto the upper surface of the flexible film substrate through a nonconductive adhesive and electrically connected to the chip connection pads. The chip connection pads are electrically connected to the corresponding solder pads. The flexible film substrate has a plurality of through-holes formed corresponding to the solder pads such that each solder pad has at least a portion exposed within the corresponding through-hole for mounting a solder ball. The present invention is characterized in that the flexible film substrate is provided with a dam and a stiffener wherein the dam is located between the chip and the chip connection pads thereby preventing the nonconductive adhesive from bleeding to contaminate the chip connection pads, and the stiffener is used to increase rigidity of the flexible film substrate. A package body is formed over the semiconductor chip and the upper surface of the flexible film substrate.

### BACKGROUND OF THE INVENTION

1. Field of the Invention

This invention generally relates to film ball grid array (BGA) packages, and more particularly to flexible film substrates for use in forming film BGA packages and manufacturing methods thereof.

2. Description of the Related Art

FIG. 1 shows a conventional film BGA package 100 typically includes a flexible film substrate 110 to support a semiconductor chip 120. The flexible film substrate is provided with a plurality of chip connection pads 110a arranged about the periphery of the semiconductor chip 120. The semiconductor chip 120 is securely attached onto the flexible film substrate 110 through a nonconductive epoxy resin and electrically connected to the chip connection pads 110a through a plurality of bonding wires 130. The chip connection pads 110a are electrically connected to a plurality of solder pads 110b through conductive traces (not shown). The flexible film substrate 110 has a plurality of through-hole 110c disposed corresponding to solder pads 110b. Each solder pad 110b has a portion exposed within the corresponding through-hole 110c for mounting a solder ball 140. The film BGA package 100 is mounted to a substrate (not shown), such as a printed circuit board, through the solder balls 140.

When a large-size semiconductor chip is mounted to the flexible film substrate, the nonconductive epoxy resin tends to bleed around the die perimeter thereby contaminating the chip connection pads disposed nearby, which is fatal to surface bondability thereof. Further, the flexible film substrate is prone to be deformed by external forces (e.g. stress due to CTE (coefficient of thermal expansion) mismatch) thereby resulting in problems of die cracking or delamination.

### SUMMARY OF THE INVENTION

It is a primary object of the present invention to provide a film BGA package comprising a semiconductor chip securely attached onto a flexible film substrate through a nonconductive adhesive and electrically connected to chip connection pads formed on the flexible film substrate wherein the flexible film substrate is provided with a dam for preventing the nonconductive adhesive from bleeding to contaminate the chip connection pads.

It is another object of the present invention to provide a film BGA package comprising a flexible film substrate to carry a semiconductor chip wherein the flexible film substrate has a stiffener formed thereon for increasing rigidity of the flexible film substrate.

A film BGA package in accordance with a preferred embodiment of the present invention generally comprises a semiconductor chip disposed on a flexible film substrate. The flexible film substrate includes a plurality of solder pads formed on the central area thereof and a plurality of chip connection pads formed on the peripheral area thereof. The solder pads are electrically connected to the corresponding chip connection pads through conductive traces formed on the upper surface of the substrate. The flexible film substrate has a plurality of through-holes formed corresponding to the solder pads such that each solder pad has at least a portion exposed within the corresponding through-hole for mounting a solder ball. The semiconductor chip is securely attached onto the flexible film substrate through a nonconductive adhesive and electrically connected to the chip connection pads. The flexible film substrate of the present invention is characterized in that a dam is provided on the upper surface at a location between the chip and the chip connection pads thereby preventing the nonconductive adhesive from bleeding to contaminate the chip connection pads. Preferably, the flexible film substrate in accordance with the present invention is provided with a stiffener substantially diagonally positioned across the chip attaching region of the substrate for increasing rigidity of the flexible film substrate. A package body is formed over the semiconductor chip and the upper surface of the flexible film substrate.

When the semiconductor chip is attached onto the flexible film substrate by the nonconductive adhesive, the dam on the flexible film substrate in accordance with the present invention can prevent the nonconductive adhesive from bleeding to contaminate the chip connection pads disposed around the chip. Further, the stiffener on the flexible film substrate can increase the rigidity of the substrate to resist external forces thereby overcoming the problems of die cracking or delamination.

The present invention further provides a method for producing a flexible film substrate comprising the steps of: (A) forming a plurality of through-holes in the central area of the flexible film; (B) laminating a metal layer on the upper surface of the flexible film; (C) etching the metal layer to form a plurality of solder pads, chip connection pads and conductive traces, wherein the solder pads are disposed corresponding to the through-holes and electrically connected to the chip connection pads through the conductive traces, and the chip connection pads are disposed on the peripheral area of the substrate; (D) forming a dam and a stiffener on the upper surfaces of the flexible film such that the dam is disposed between the central area and the chip connection pads, and the stiffener is substantially diagonally positioned across the chip attaching region of the substrate. The dam and the stiffener in accordance with the present invention are preferably formed from photoimagable solder mask.

Other objects, advantages, and novel features of the invention will become more apparent from the following detailed description when taken in conjunction with the accompanying drawings.

### BRIEF DESCRIPTION OF THE DRAWINGS

FIG. 1 is a cross sectional view of a conventional film BGA package;

FIG. 2 is a cross sectional view of a film BGA package according to a first embodiment of the present invention;

FIG. 3-6 are cross sectional views for illustrating a method for producing a flexible film substrate in accordance with the present invention;

FIG. 7 a top plan view of a flexible film substrate according to a first embodiment of the present invention;

FIG. 8 a top plan view of a flexible film substrate according to a second embodiment of the present invention; and

FIG. 9 is a top plan view of a flexible film substrate according to a third embodiment of the present invention.

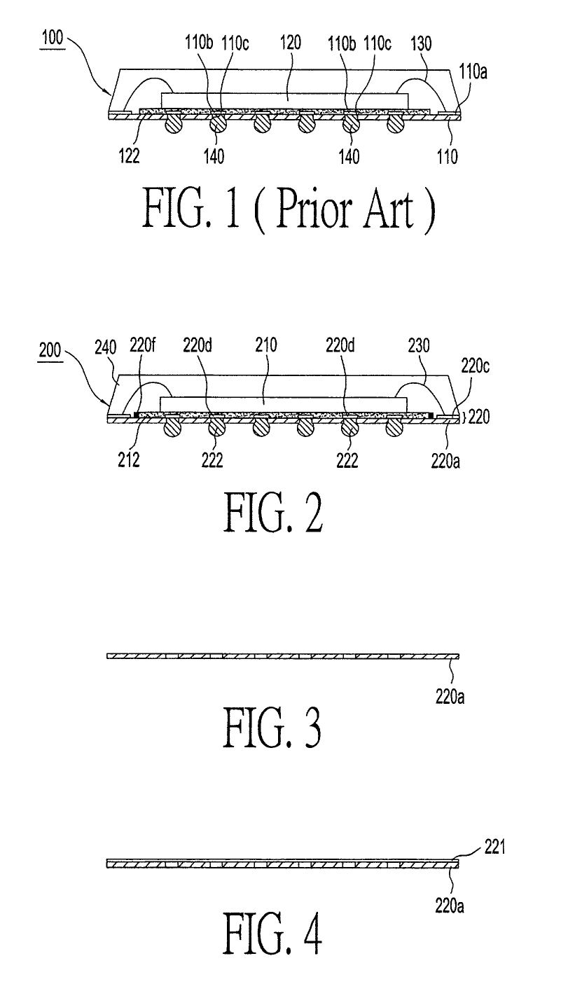

### DETAILED DESCRIPTION OF THE PREFERRED EMBODIMENT

FIG. 2 illustrates a film BGA package 200 according to a first embodiment of the present invention mainly comprising a semiconductor chip 210 securely attached onto the upper surface of a flexible film substrate 220 by a nonconductive adhesive 212 (e.g. epoxy resin).

Referring to FIG. 2 and FIG. 7, the flexible film substrate 220 is mainly formed from a flexible film 220a having a chip attaching area 220b adapted for receiving the semiconductor chip 210. The upper surface of flexible film substrate film 220a is provided with a plurality of chip connection pads 220c arranged about the periphery of the chip attaching area 220b and a plurality of solder pads 220d substantially disposed in the chip attaching area 220b. Each solder pad 220d is electrically connected to the corresponding chip connection pad 220c through a conductive trace 220e formed on the upper surface of the flexible film 220a. The chip connection pads 220c are electrically connected to the semiconductor chip 210 through a plurality of bonding wires 230. The flexible film 220a has a plurality of through-holes formed corresponding to the solder pads 220d such that each solder pad 220d has at least a portion exposed within the corresponding through-hole for mounting a solder ball 222. A package body 240 is formed over the semiconductor chip 210 and the upper surface of the flexible film substrate 220. The plurality of solder balls 222 are provided on the lower surface of the flexible film substrate 220 for making external electrical connection.

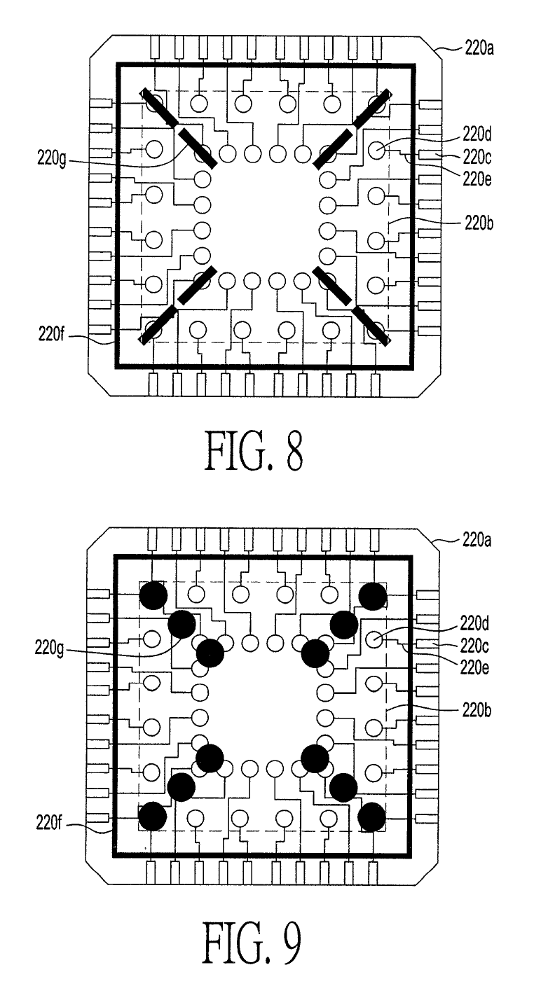

Referring to FIG. 2 and FIG. 7 again, the present invention is characterized in that the flexible film substrate 220 is provided with a dam 220f and a stiffener 220g. The dam 220f is located between the chip attaching area 220b and the chip connection pads 220c for preventing the nonconductive adhesive 212 from bleeding to contaminate the chip connection pads 220c. The stiffener 220g is substantially diagonally positioned across the chip attaching region 220b thereby increasing the bond line thickness and the fillet height of the nonconductive adhesive. The stiffener 220g is preferably formed in an broken “X” pattern (see FIG. 7, FIG. 8, and FIG. 9) in order to obtain the best reinforcing effect without interfering the flow of the nonconductive adhesive. It should be understood that the stiffener in accordance with the present invention may be bar-like or circular as shown in FIG. 7, FIG. 8 or FIG. 9.

FIGS. 3-6 show a method for producing a flexible film substrate in accordance with the present invention.

Referring to FIG. 3, a plurality of through-holes are formed in the flexible film 220a by conventional techniques such as punching or laser drilling. The through-holes are formed at locations corresponding to the solder pads 220d disposed at the bottom section of the package 200 (referring to FIG. 2). Preferably, the flexible film 220a is made of polyimide such that the flexible film is given properties that allow it to pass reliability tests.

Referring to FIG. 4, a metal layer 221 such as a copper foil is laminated on the flexible film 220a by conventional methods such as thermocompression.

Referring to FIG. 5, the chip connection pads 220c, the solder pads 220d and conductive traces 220e (not shown in FIG. 5) are formed via photolithography and etching which comprise the steps of: (A) applying a photoresist layer on the surface of the metal layer 221; (B) pattern (referring to FIG. 7) transferring by photolithography; (C) removing the unprotected portions of the metal layer to form the corresponding chip connection pads 220c, solder pads 220d and conductive traces 220e by etching; and (D) removing the remaining photoresist layer. Preferably, the chip connection pads 220c, the solder pads 220d and conductive traces 220e are provided with a metal coating formed on the surfaces thereof which are not covered by the flexible film 220a. The metal coating can be plated by using conventional techniques. Preferably, a layer of nickel is plated thereon and then a layer of gold is plated on the nickel layer. Since the metal coating is also formed on the connection pads adapted for electrical connecting to the chip, the metal coating should be formed of materials that allow a good bond to the conventional bonding wire material.

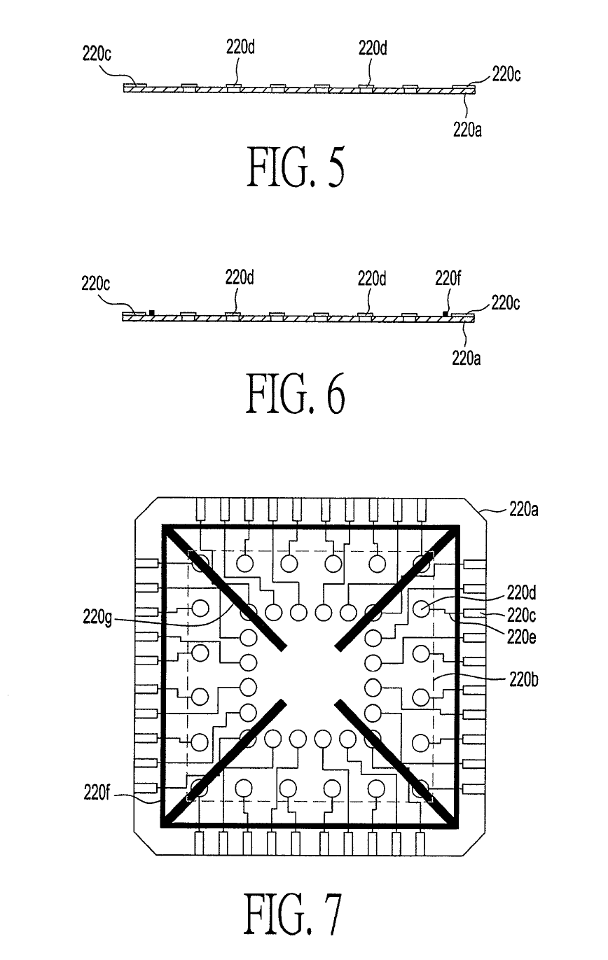

Referring to FIG. 6, the dam 220f and the stiffener 220g (not shown in FIG. 6) can be formed by screen printing with epoxy resin. Alternatively, a photoimagable solder mask can be formed over the upper surface of the flexible film, transferred a predetermined pattern (referring to FIG. 7, FIG. 8 or FIG. 9), and then developed to form the dam 220f and the stiffener 220g. The thickness of the dam 220f and the stiffener 220g is preferably 1.0-3.0 mil, more preferably 1.5-2.5 mil.

In accordance with the present invention, the dam on the flexible film substrate can prevent the nonconductive adhesive from bleeding to contaminate the chip connection pads disposed around the chip during the attaching of the semiconductor chip onto the flexible film substrate by the nonconductive adhesive thereby assuring the surface bondability of the chip connection pads.

According to another aspect of the present invention, the stiffener on the flexible film substrate can increase the rigidity of the substrate to resist external forces, e.g. stress due to CTE (coefficient of thermal expansion) mismatch. Further, the stiffener can increase the bond line thickness, which in turn helps to absorb the stress due to CTE mismatch thereby improving the problems of die cracking or delamination. Besides, the stiffener can also increase the fillet height thereby reducing the volume of the molding compound above the semiconductor chip; this reduces the contraction thereof after curing thereby overcoming the problem of package warpage and reducing stress imposed on the semiconductor chip.

Although the invention has been explained in relation to its preferred embodiment, it is to be understood that many other possible modifications and variations can be made without departing from the spirit and scope of the invention as hereinafter claimed.

What is claimed is:

1. A film ball grid array (BGA) package comprising:
a flexible film substrate comprising a flexible film having opposing upper and lower surfaces, the upper surface of the flexible film has a chip attaching area; a plurality of chip connection pads arranged about the periphery of the chip attaching area; a plurality of solder pads on the upper surface of the flexible film electrically connected to the corresponding chip connection pads, wherein the flexible film has a plurality of through-holes formed corresponding to the solder pads; and a dam on the upper surface of the flexible film disposed between the chip attaching area and the chip connection pads;
a plurality of solder balls mounted to the plurality of solder pads of the flexible film substrate for making external electrical connection;
a semiconductor chip securely attached onto the chip attaching area of the flexible film substrate, the chip having a plurality of bonding pads electrically connected to the corresponding chip connection pads; and
a package body formed over the semiconductor chip and the upper surface of the flexible film substrate.

2. The film BGA package as claimed in claim 1, wherein the flexible film is made of polyimide.

3. The film BGA package as claimed in claim 1, wherein the dam is formed from photoimagable solder mask.

4. The film BGA package as claimed in claim 1, wherein the dam is formed of epoxy resin.

5. The film BGA package as claimed in claim 1, further comprising a stiffener formed on the upper surface of the flexible film for increasing the rigidity of the flexible film substrate.

6. The film BGA package as claimed in claim 5, wherein the stiffener is formed from photoimagable solder mask.

7. The film BGA package as claimed in claim 5, wherein the stiffener is formed of epoxy resin.

8. A flexible film substrate for use in forming a film BGA package, the flexible film substrate comprising:
a flexible film having opposing upper and lower surfaces, the upper surface of the flexible film has a chip attaching area adapted for supporting a semiconductor chip;
a plurality of chip connection pads arranged about the periphery of the chip attaching area for electrically connected to the semiconductor chip;
a plurality of solder pads on the upper surface of the flexible film electrically connected to the corresponding chip connection pads, wherein the flexible film has a plurality of through-holes formed corresponding to the solder pads; and
a dam on the upper surface of the flexible film disposed between the chip attaching area and the chip connection pads.

9. The flexible film substrate as claimed in claim 8, wherein the flexible film is made of polyimide.

10. The flexible film substrate as claimed in claim 8, wherein the dam is formed from photoimagable solder mask.

11. The flexible film substrate as claimed in claim 8, wherein the dam is formed of epoxy resin.

12. The flexible film substrate as claimed in claim 8, further comprising a stiffener formed on the upper surface of the flexible film for increasing the rigidity of the flexible film substrate.

13. The flexible film substrate as claimed in claim 12 wherein the stiffener is formed from photoimagable solder mask.

14. The flexible film substrate as claimed in claim 12, wherein the stiffener is formed of epoxy resin.

15. The flexible film substrate as claimed in claim 8, wherein the substrate is one of a plurality of substrates formed in a strip configuration for use in forming a plurality of substrate-based semiconductor chip package.

16. A method for manufacturing a flexible film substrate comprising the steps of:
providing a flexible film having opposing upper and lower surfaces, the upper surface of the flexible film has a chip attaching area adapted for supporting a semiconductor chip;
forming a plurality of through-holes in the flexible film;
laminating a metal layer on the upper surface of the flexible film;
etching the metal layer to form a plurality of solder pads, chip connection pads and conductive traces, wherein the solder pads are disposed corresponding to the through-holes and electrically connected to the chip connection pads through the conductive traces; and
forming a dam on the upper surfaces of the flexible film such that the dam is disposed between the chip attaching area and the chip connection pads.

17. The method as claimed in claim 16, wherein the flexible film is made of polyimide.

18. The method as claimed in claim 16, wherein the step of forming the dam comprises applying a photoimagable solder mask over the upper surface of the flexible film, transferring a predetermined pattern, and developing to form the dam.

19. The method as claimed in claim 16, wherein the step of forming the dam comprises screen printing with epoxy resin to form the dam.

20. The method as claimed in claim 16, further comprising a step of forming a stiffener on the upper surface of the flexible film for increasing rigidity of the flexible film substrate during the step of forming the dam.

21. The method as claimed in claim 20, wherein the step of forming the stiffener comprises applying a photoimagable solder mask over the upper surface of the flexible film, transferring a predetermined pattern, and developing to form the stiffener.

22. The method as claimed in claim 20, wherein the step of forming the stiffener comprises screen printing with epoxy resin to form the stiffener.
